(19) United States
(12) Patent Application Publication
(10) Pub. No.: US 2025/0192019 A1
(43) Pub. Date: Jun. 12, 2025

(54) SEMICONDUCTOR PACKAGE INCLUDING INTERPOSER AND METHOD FOR MANUFACTURING THE SAME

(71) Applicant: SAMSUNG ELECTRONICS CO., LTD., Suwon-si (KR)

(72) Inventors: Byung Ho Kim, Suwon-si (KR); Youngchan Ko, Suwon-si (KR); Yongkoon Lee, Suwon-si (KR); MyungDo Cho, Suwon-si (KR); Jaeyoung Choi, Suwon-si (KR)

(73) Assignee: SAMSUNG ELECTRONICS CO., LTD., Suwon-si (KR)

(21) Appl. No.: 18/794,712

(22) Filed: Aug. 5, 2024

(30) Foreign Application Priority Data
Dec. 8, 2023 (KR) 10-2023-0177962

(51) Int. Cl. H01L 23/498; H01L 21/48; H01L 21/56; H01L 23/00; H01L 23/12; H01L 23/538; H01L 25/065; H05K 1/18

(52) U.S. Cl. CPC H01L 23/49833; H01L 21/4857; H01L 21/563; H01L 21/568; H01L 23/12; H01L 23/49838; H01L 23/5381; H01L 23/5385; H01L 23/5386; H01L 24/16; H01L 24/32; H01L 24/73; H01L 25/0655; H01L 2224/16227; H01L 2224/32225; H01L 2224/73204; H01L 2224/73253; H01L 2924/1815; H05K 1/181

(57) ABSTRACT

An interposer is provided. The interposer includes a first redistribution structure; a device die on the first redistribution structure, the device die having a first surface facing the first redistribution structure and a second surface which is opposite to the first surface; a plurality of first connection members on the second surface of the device die; an insulating member disposed on the second surface of the device die and covering first portions of side surfaces of the plurality of first connection members; a plurality of second connection members on the first redistribution structure; a molding material disposed on the first redistribution structure and covering each of the device die, second portions of the side surfaces of the plurality of first connection members, the insulating member, and the plurality of second connection members; and a second redistribution structure on the molding material.

### CROSS-REFERENCE TO RELATED APPLICATION

This application claims priority to Korean Patent Application No. 10-2023-0177962, filed in the Korean Intellectual Property Office, on Dec. 8, 2023, the disclosure of which is incorporated by reference herein in its entirety.

### BACKGROUND

### (a) Field

The present disclosure relates to a semiconductor package including an interposer and a method for manufacturing the same.

### (b) Description of Related Art

As lighter, thinner, and smaller semiconductor chips have been developed, semiconductor chips have been increasingly required to have fine-pitch input/output (1/O) terminals, and as intermediate media for electrically coupling such fine-pitch 1/O terminals of semiconductor chips to general-pitch 1/O terminals of a substrate, interposers have been used.

In a semiconductor package in which semiconductor chips are arranged side by side, the semiconductor chips may be electrically coupled to one another for communication among the semiconductor chips, and the semiconductor chips may be electrically coupled to a substrate for communication between the semiconductor chips and the substrate. In order to couple the semiconductor chips and the substrate as described above, interposers may include bridge structures.

In addition, interposers may include surface mount devices (SMDs) to provide additional functions or programs to semiconductor packages and to improve power integrity (PI) of semiconductor packages.

In a process of manufacturing an interposer, in order to mount such a bridge structure or surface mount device (SMD) on a redistribution structure, it is required to move the bridge structure or the surface mount device (SMD) by applying a vacuum to bumps formed on the upper surface of the bridge structure or the upper surface of the surface mount device (SMD) with semiconductor equipment. However, when the bumps are stressed by the equipment, or the bumps are misaligned, problems may occur. For example, in the process of moving the bridge structure or the surface mount device (SMD) by applying a vacuum to the bumps formed on the upper surface of the bridge structure or the upper surface of the surface mount device (SMD), the bumps may be short-circuited or come off, or defects may occur in the bumps.

Therefore, there is a need for a new semiconductor package technology capable of solving the problems of semiconductor packages according to the related art.

### SUMMARY

One or more example embodiments cover some portions of the side surfaces of connection members on a device die in an interposer from the lowest ends of the side surfaces of the connection members with an insulating member and cover the other portions of the side surfaces of the connection members with a molding material, such that the connection members can be protected.

According to an aspect of an example embodiment, an interposer includes: a first redistribution structure; a device die on the first redistribution structure, the device die having a first surface facing the first redistribution structure and a second surface which is opposite to the first surface; a plurality of first connection members on the second surface of the device die; an insulating member disposed on the second surface of the device die and covering first portions of side surfaces of the plurality of first connection members; a plurality of second connection members on the first redistribution structure; a molding material disposed on the first redistribution structure and covering each of the device die, second portions of the side surfaces of the plurality of first connection members, the insulating member, and the plurality of second connection members; and a second redistribution structure on the molding material.

According to another aspect of an example embodiment, a semiconductor package includes: a substrate; a first redistribution structure on the substrate; a device die on the first redistribution structure, the device die having a first surface facing the first redistribution structure and a second surface which is opposite to the first surface; a plurality of first connection members on the second surface of the device die; an insulating member disposed on the second surface of the device die and covering first portions of side surfaces of the plurality of first connection members; a plurality of second connection members on the first redistribution structure; a molding material disposed on the first redistribution structure and covering each of the device die, second portions of the side surfaces of the plurality of first connection members, the insulating member, and the plurality of second connection members; a second redistribution structure on the molding material; a first semiconductor die on the second redistribution structure; and a second semiconductor die on the second redistribution structure adjacent the first semiconductor die.

According to another aspect of an example embodiment, a method of manufacturing an interposer includes: providing a device die having a first surface and a second surface which is opposite to the first surface; forming a plurality of first connection members on the second surface of the device die; forming an insulating member on the second surface of the device die, wherein the insulating member covers first portions of side surfaces of the plurality of first connection members; forming a first redistribution structure on a carrier; forming a plurality of second connection members on the first redistribution structure; attaching the first surface of the device die to the first redistribution structure; covering each of the device die, the plurality of first connection members, the insulating member, and the plurality of second connection members on the first redistribution structure with a molding material; planarizing the molding material, the plurality of first connection members, and the plurality of second connection members, wherein the molding material covers each of the device die, second portions of the side surfaces of the plurality of first connection members, the insulating member, and the plurality of second connection members; and forming a second redistribution structure on the molding material.

### BRIEF DESCRIPTION OF DRAWINGS

The above and other objects and features will be more clearly understood from the following description, taken in conjunction with the accompanying drawings.

FIG. 1 is a cross-sectional view illustrating an interposer according to an example embodiment.

FIG. 2 is an enlarged cross-sectional view of a device die of an interposer according to an example embodiment.

FIG. 3 is a cross-sectional view illustrating a semiconductor package including an interposer according to an example embodiment.

FIGS. 4 and 5 are cross-sectional views illustrating a method of forming first connection members and an insulating member on a second device die according to an example embodiment.

FIGS. 6 to 11 are cross-sectional views for explaining a method for manufacturing an interposer according to an example embodiment.

FIGS. 12 to 17 are cross-sectional views for explaining a method for manufacturing a semiconductor package according to an example embodiment.

### DETAILED DESCRIPTION

Embodiments will now be described more fully with reference to the accompanying drawings, in which example embodiments are shown. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto.

Throughout this specification, when a part is referred to as being “connected” to another part, it may be directly connected to the other part, or may be connected to the other part indirectly with any other elements interposed therebetween. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

Further, the phrase “on a plane”, indicates that a target part is viewed from above, and the phrase “on a cross-section”, indicates that a cross-section obtained by cutting a target part vertically is viewed from the side.

Hereinafter, a semiconductor package 200 including an interposer 100 of an example embodiment, and a method for manufacturing the same will be described with reference to the drawings.

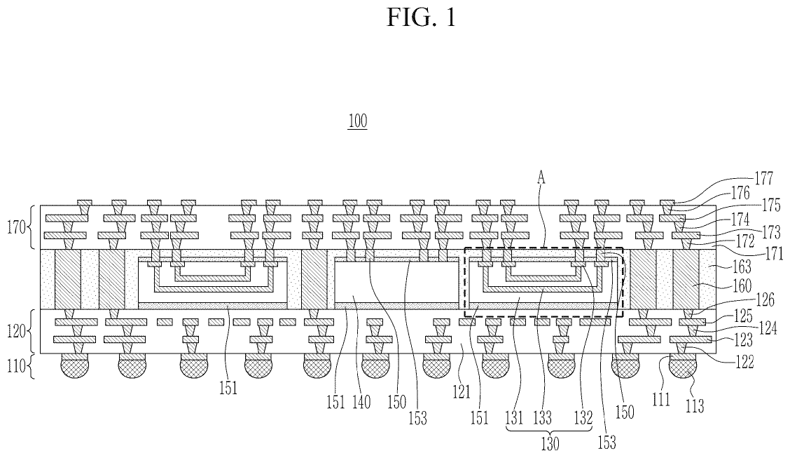

FIG. 1 is a cross-sectional view illustrating the interposer 100.

Referring to FIG. 1, the interposer 100 includes an external connection structure 110, a first redistribution structure 120, a first device die 130, a second device die 140, first connection members 150, insulating members 153, second connection members 160, a first molding material 163, and a second redistribution structure 170. According to an example embodiment, the interposer 100 may include a composite interposer including a redistribution structure and a molded interposer coupled to each other. According to example embodiments, the interposer 100 may be manufactured based on a fan-out wafer-level packaging (FOWLP) or fan-out panel-level packaging (FOPLP) technology.

The external connection structure 110 is disposed on the lower surface of the first redistribution structure 120. The external connection structure 110 includes conductive pads 111 and external connection members 113. Each of the conductive pads 111 is disposed between a first redistribution via 122 of the first redistribution structure 120 and an external connection member 113. Each of the conductive pads 111 electrically couples the first redistribution via 122 of the first redistribution structure 120 to the external connection member 113. The external connection members 113 electrically couple the interposer 100 to an external device.

The first redistribution structure 120 includes a first dielectric 121, and the first redistribution vias 122, first redistribution lines 123, second redistribution vias 124, second redistribution lines 125, and third redistribution vias 126 in the first dielectric 121. In other example embodiments, the first redistribution structure 120 may include fewer or more redistribution lines and redistribution vias.

The first dielectric 121 protects and insulates the first redistribution vias 122, the first redistribution lines 123, the second redistribution vias 124, the second redistribution lines 125, and the third redistribution vias 126. On the upper surface of the first dielectric 121, the first device die 130, the second device die 140, the second connection members 160, and the first molding material 163 are disposed. On the lower surface of the first dielectric 121, the external connection structure 110 is disposed.

Each of the first redistribution vias 122 is disposed between a first redistribution line 123 and a conductive pad 111. Each of the first redistribution vias 122 electrically couples a first redistribution line 123 to an external connection member 113 coupled to a conductive pad 111 in a vertical direction. Each of the first redistribution lines 123 is disposed between a first redistribution via 122 and a second redistribution via 124. Each of the first redistribution lines 123 electrically couples a first redistribution via 122 and a second redistribution via 124 in a horizontal direction. Each of the second redistribution vias 124 is disposed between a first redistribution line 123 and a second redistribution line 125. Each of the second redistribution vias 124 electrically couples a second redistribution line 125 to a first redistribution line 123 in a vertical direction. Each of the second redistribution lines 125 is disposed between a second redistribution via 124 and a third redistribution via 126. Each of the second redistribution lines 125 electrically couples a second redistribution via 124 and a third redistribution via 126 in a horizontal direction. Each of the third redistribution vias 126 is disposed between a second connection member 160 and a second redistribution line 125. Each of the third redistribution vias 126 electrically couples a second connection member 160 to a second redistribution line 125 in a vertical direction.

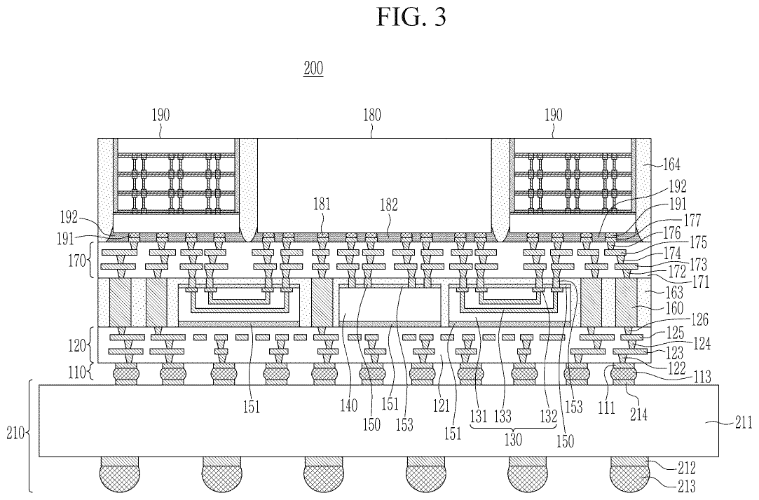

The first device die 130 is disposed between the first redistribution structure 120 and the second redistribution structure 170. The first device die 130 has a first surface facing the first redistribution structure 120, and a second surface which is the opposite surface of the first surface. In an example embodiment, the first device die 130 may include a bridge die. According to an example embodiment, the bridge die may include a silicon bridge die. The first device die 130 electrically couples a first semiconductor die (see the reference symbol “180” in FIG. 3) and a second semiconductor die (see the reference symbol “190” in FIG. 3) which are disposed on the second redistribution structure 170. On the first surface of the first device die 130, first connection members 150 and an insulating member 153 are disposed. The second surface of the first device die 130 is attached to the first redistribution structure 120 by an adhesive member 151. In an example embodiment, the adhesive member 151 may be die attach film (DAF).

The first device die 130 includes a die base 131, and connection pads 132 and wiring lines 133 in the die base 131. The wiring lines 133 included in the die base 131 transfer data quickly in a horizontal direction. Therefore, the first device die 130 may optimize the signal transfer path between a first semiconductor die 180 and a second semiconductor die 190 disposed on the second redistribution structure 170 coupled to the first device die 130 to reduce power consumption, thereby improving the performance of the semiconductor package. In an example embodiment, each of the connection pads 132 and the wiring lines 133 may include any one or any combination of copper, aluminum, silver, tin, gold, nickel, lead, titanium, and alloys thereof.

The second device die 140 is disposed between the first redistribution structure 120 and the second redistribution structure 170. The second device die 140 has a first surface facing the first redistribution structure 120, and a second surface which is the surface opposite to the first surface. In an example embodiment, the second device die 140 may include a surface mount device (SMD). In an example embodiment, the second device die 140 may provide additional functions or programming to the entire semiconductor package (see the reference symbol “200” in FIG. 3). In an example embodiment, the second device die 140 may include any one or any combination of a register, an inductor, a capacitor, and a jumper. In an example embodiment, the second device die 140 may include an integrated stack capacitor (ISC) structure. On the first surface of the second device die 140, first connection members 150 and an insulating member 153 are disposed. The second surface of the second device die 140 is attached to the first redistribution structure 120 by an adhesive member 151. In an example embodiment, the adhesive member 151 may be die attach film (DAF).

The first connection members 150 are disposed on the first surface of the first device die 130 and the first surface of the second device die 140. Each of the first connection members 150 is disposed between a fourth redistribution via 172 of the second redistribution structure 170 and a connection pad 132 of the first device die 130, or between a fourth redistribution via 172 of the second redistribution structure 170 and a wiring line of the second device die 140. Each of the first connection members 150 electrically couples a fourth redistribution via 172 of the second redistribution structure 170 to a connection pad 132 of the first device die 130, or electrically couples a fourth redistribution via 172 of the second redistribution structure 170 to a wiring line of the second device die 140. The first connection members 150 are disposed through the insulating members 153 and the first molding material 163. The side surfaces of the first connection members 150 are surrounded by the insulating members 153 and the first molding material 163. In an example embodiment, the first connection members 150 may include micro bumps.

The insulating members 153 are disposed on the first surface of the first device die 130 and the first surface of the second device die 140. The insulating members 153 cover some portions (first portions) of the side surfaces of the first connection members 150 from the lowest ends of the side surfaces of the first connection members 150. In an example embodiment, the insulating members 153 may include a photoimageable dielectric (PID). The photoimageable dielectric is a material applicable to a photolithography process to form fine patterns. In an example embodiment, the photoimageable dielectric (PID) may include a polyimide-based photosensitive polymer, a novolac-based photosensitive polymer, polybenzoxazole, a silicon-based polymer, an acrylate-based polymer, or an epoxy-based polymer.

In an example embodiment, the insulating member 153 has an upper surface having a constant level in a horizontal direction (an upper surface having constant surface roughness). In an example embodiment, the insulating members 153 may include a photosensitive dielectric (PID) including no fillers. According to example embodiments, a photoimageable dielectric material including no fillers may be used to minimize the surface roughness of the insulating members. In this case, fine wiring may be formed after performing a chemical mechanical polishing (CMP) process.

According to example embodiments, in the process of manufacturing the interposer 100, it is possible to protect the first connection members 150 by the insulating members 153. Accordingly, in a process of moving the first device die 130 and the second device die 140 by applying a vacuum to the first connection members 150 formed on the upper surface of the first device die 130 and the upper surface of the second device die 140, it is possible to prevent the first connection members 150 from being short-circuited, prevent the first connection members 150 from coming off, and prevent defects from occurring in the first connection members 150.

The second connection members 160 are disposed on the upper surface of the first redistribution structure 120. Each of the second connection members 160 is disposed between a third redistribution via 126 of the first redistribution structure 120 and a fourth redistribution via 172 of the second redistribution structure 170. Each of the second connection members 160 electrically couples a fourth redistribution via 172 of the second redistribution structure 170 to a third redistribution via 126 of the first redistribution structure 120. The second connection members 160 are disposed through the first molding material 163. The side surfaces of the second connection members 160 are surrounded by the first molding material 163. In an example embodiment, the second connection members 160 may include conductive posts.

The first molding material 163 is disposed on the first redistribution structure 120 so as to cover the first device die 130, the second device die 140, and the second connection members 160. The first molding material 163 protects the first device die 130, the second device die 140, and the second connection members 160 from the external environment. Accordingly, it is possible to secure electrical or mechanical stability of the interposer 100.

Further, the first molding material 163 covers second portions of the side surfaces of the first connection members 150 except for the first portions of the side surfaces of the first connection members 150 covered by the insulating members 153. As described above, the first connection members 150 formed on the upper surface of the first device die 130 and the upper surface of the second device die 140 may be covered with the combination of the insulating members 153 and the first molding material 163. Accordingly, it is possible to suppress warpage of the semiconductor package by variously changing the kinds of the insulating members 153 and the first molding material 163 and the ratio between the insulating members 153 and the first molding material 163.

The second redistribution structure 170 is disposed on the first connection members 150, the second connection members 160, and the first molding material 163. The second redistribution structure 170 includes a second dielectric 171; the fourth redistribution vias 172, third redistribution lines 173, fifth redistribution vias 174, fourth redistribution lines 175, and sixth redistribution vias 176 in the second dielectric 171; and second bonding pads 177 on the second dielectric 171. In other example embodiments, the second redistribution structure 170 may include fewer or more redistribution lines, redistribution vias, and bonding pads.

The second dielectric 171 protects and insulates the fourth redistribution vias 172, the third redistribution lines 173, the fifth redistribution vias 174, the fourth redistribution lines 175, and the sixth redistribution vias 176. On the lower surfaces of the second dielectric 171, the first connection members 150, the second connection members 160, and the first molding material 163 are disposed.

Each of the fourth redistribution vias 172 is disposed between a first connection member 150 and a third redistribution line 173, or between a second connection member 160 and a third redistribution line 173. Each of the fourth redistribution vias 172 electrically couples a third redistribution line 173 to a first connection member 150, or electrically couples a third redistribution line 173 to a second connection member 160, in a vertical direction. Each of the third redistribution lines 173 is disposed between a fourth redistribution via 172 and a fifth redistribution via 174. Each of the third redistribution lines 173 electrically couples a fourth redistribution via 172 and a fifth redistribution via 174 in a horizontal direction. Each of the fifth redistribution vias 174 is disposed between a third redistribution line 173 and a fourth redistribution line 175. Each of the fifth redistribution vias 174 electrically couples a fourth redistribution line 175 to a third redistribution line 173 in a vertical direction. Each of the fourth redistribution lines 175 is disposed between a fifth redistribution via 174 and a sixth redistribution via 176. Each of the fourth redistribution lines 175 electrically couples a fifth redistribution via 174 and a sixth redistribution via 176 in a horizontal direction. Each of the sixth redistribution vias 176 is disposed between a fourth redistribution line 175 and a second bonding pad 177. Each of the sixth redistribution vias 176 electrically couples a second bonding pad 177 to a fourth redistribution line 175 in a vertical direction. Each of the second bonding pads 177 is disposed on a sixth redistribution via 176. Each of the second bonding pads 177 electrically couples a connection member (see the reference symbol “181” in FIG. 3) of the first semiconductor die 180 to a sixth redistribution via 176, or electrically couples a connection member (see the reference symbol “191” in FIG. 3) of the second semiconductor die 190 to a sixth redistribution via 176.

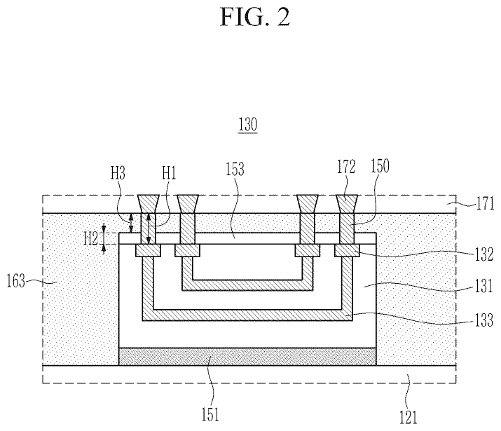

FIG. 2 is an enlarged cross-sectional view of the first connection members 150 and the insulating member 153 on the second device die 140 in region A of the interposer 100 of FIG. 1.

Referring to FIGS. 1 and 2, first connection members 150 and an insulating member 153 are disposed on the first surface of the second device die 140. In an example embodiment, the first connection members 150 may have a thickness H1 of about 30 μm to about 50 μm in the vertical direction. In an example embodiment, the insulating member 153 may have a thickness H2 of about 5 μm to about 25 μm in the vertical direction. In an example embodiment, the insulating member 153 may cover the side surface of each of the first connection members 150 to about 10% to about 50% of the total height of the corresponding side surface. In the case where the height of the insulating member 153 is about 10% or less of the total height of the side surface of each of the first connection members 150, in the process of moving the first device die 130 and the second device die 140 by applying a vacuum to the first connection members 150 during the process of manufacturing the interposer, it is difficult to prevent the first connection members 150 from being short-circuited, prevent the first connection members 150 from coming off, and prevent defects from occurring in the first connection members 150. In the case where the height of the insulating member 153 is about 50% or more of the total height of the side surface of each of the first connection members 150, in a process of grinding the upper surfaces of the first connection members 150 and the upper surface of the first molding material 163 during the process of manufacturing the interposer, the insulating member 153 may hinder the upper surfaces of the first connection members 150 to be ground.

The first molding material 163 covers the second portions of the side surfaces of the first connection members 150 except for the first portions of the side surfaces of the first connection members 150 covered by the insulating member 153. On the insulating member 153, the first molding material 163 may have a thickness H3 in the vertical direction.

Each of the first connection members 150 has a lower surface which is even with a level of the second surface of the first device die 130 or the second surface of the second device die 140. The insulating members 153 have lower surfaces which are in direct contact with the second surface of the first device die 130 and the second surface of the second device die 140. The insulating members 153 have lower surfaces which are even with a level of the lower surfaces of the first connection members 150.

The same contents shown and described for the first connection members 150 and the insulating member 153 on the first device die 130 may be applied in a substantially similar manner to the first connection members 150 and the insulating member 153 on the second device die 140.

FIG. 3 is a cross-sectional view illustrating a semiconductor package 200 including the interposer 100 of FIG. 1.

Referring to FIGS. 1 and 3, the semiconductor package 200 includes the interposer 100, the first semiconductor die 180, one or more second semiconductor dies 190, a second molding material 164, and a printed circuit board 210. In an example embodiment the semiconductor package 200 may be manufactured based on a fan-out wafer-level packaging (FOWLP) or fan-out panel-level packaging (FOPLP) technology.

The first semiconductor die 180 is disposed on the second redistribution structure 170. The first semiconductor die 180 is disposed side by side with (i.e., adjacent) the second semiconductor dies 190. The first semiconductor die 180 is electrically coupled to the second redistribution structure 170 by connection members 181. In an example embodiment, the first semiconductor die 180 may include a logic die. In an example embodiment, the first semiconductor die 180 may include a system-on-chip (SoC). In an example embodiment, the first semiconductor die 180 may include any one or any combination of central processing units (CPUs) and graphic processing units (GPUs).

Each of the connection members 181 is disposed between a second bonding pad 177 and the first semiconductor die 180 so as to electrically couple the first semiconductor die 180 to the second bonding pad 177. In an example embodiment, the connection members 181 may include micro bumps or solder balls. In an example embodiment, the connection members 181 may include any one or any combination of tin, silver, lead, nickel, copper, or alloys thereof.

An insulating member 182 may be positioned between the second redistribution structure 170 and the first semiconductor die 180 so as to surround and protect the connection members 181 and the second bonding pads 177. In an example embodiment, the insulating member 182 may include non-conductive film (NCF). In an example embodiment, the insulating member 182 may include a capillary underfill (CUF).

One or more second semiconductor dies 190 are disposed on the second redistribution structure 170. The second semiconductor dies 190 are disposed side by side with (i.e., adjacent) the first semiconductor die 180. The second semiconductor dies 190 are electrically coupled to the second redistribution structure 170 by connection members 191. In an example embodiment, the second semiconductor dies 190 may include a high bandwidth memory (HBM). The high bandwidth memory (HBM) is a high-performance three-dimensional (3D) stacked dynamic random access memory (DRAM). The high bandwidth memory (HBM) may be manufactured by vertically stacking memory dies on a buffer chip to form one memory stack by performing hybrid bonding or using micro bumps.

Each of the connection members 191 is disposed between a second bonding pad 177 and a second semiconductor die 190 so as to electrically couple the second semiconductor die 190 to the second bonding pad 177. In an example embodiment, the connection members 191 may include micro bumps or solder balls. In an example embodiment, the connection members 191 may include any one or any combination of tin, silver, lead, nickel, copper, or alloys thereof.

An insulating member 192 may be positioned between the second redistribution structure 170 and the second semiconductor dies 190 so as to surround and protect the connection members 191 and the second bonding pads 177. In an example embodiment, the insulating member 192 may include non-conductive film (NCF). In an example embodiment, the insulating member 192 may include a capillary underfill (CUF).

The second molding material 164 is positioned on the second redistribution structure 170 so as to cover the first semiconductor die 180, one or more second semiconductor dies 190, and the insulating members 182 and 192. The second molding material 164 protects the first semiconductor die 180, one or more second semiconductor dies 190, and the insulating members 182 and 192 from the external environment. Accordingly, it is possible to secure the electrical or mechanical stability of the semiconductor package 200.

The printed circuit board 210 is disposed on the lower surface of the first redistribution structure 120, and is electrically coupled to the external connection structure 110. The printed circuit board 210 includes a substrate base 211, conductive pads 212, and connection members 213. The substrate base 211 is electrically coupled to an external device by the conductive pads 212 and the connection members 213. In an example embodiment, the conductive pads 212 may include any one or any combination of copper, nickel, zinc, gold, silver, platinum, palladium, chromium, titanium, and alloys thereof. In an example embodiment, the connection members 213 may include any one or any combination of tin, silver, lead, nickel, copper, or alloys thereof. In an example embodiment, the connection members 213 may include solder balls.

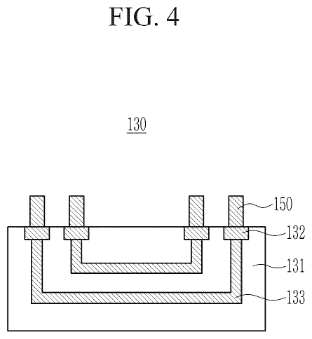

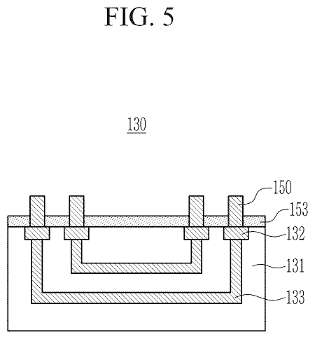

FIGS. 4 and 5 are cross-sectional views illustrating a method of forming the first connection members 150 and the insulating member 153 on the first device die 130. The method of forming the first connection members 150 and the insulating member 153 on the first device die 130 may be applied in a substantially similar manner to a method of forming the first connection members 150 and the insulating member 153 on the second device die 140.

FIG. 4 is a cross-sectional view illustrating a method of forming the first connection members 150 on the first device die 130.

Referring to FIG. 4, the first connection members 150 are formed on the first device die 130. The first connection members 150 are formed by disposing photoresist on the die base 131 of the first device die 130, selectively exposing and developing the photoresist to form photoresist patterns including opening, and filling the openings with a conductive material. In an example embodiment, the first connection members 150 may include any one or any combination of tin, silver, lead, nickel, copper, or alloys thereof. In an example embodiment, the first connection members 150 may be formed by performing a sputtering process. In another example embodiment, the first connection members 150 may be formed by forming seed metal layers and then performing an electroplating process.

FIG. 5 is a cross-sectional view illustrating a method of forming the insulating member 153 on the first device die 130.

Referring to FIG. 5, the insulating member 153 is formed on the die base 131 of the first device die 130 so as to surround some portions (first portions) of the side surfaces of the first connection members 150. In an example embodiment, the insulating member 153 may be formed by performing spin coating.

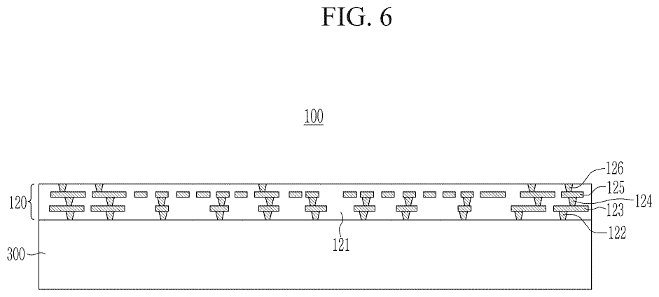

FIGS. 6 to 11 are cross-sectional views for explaining a method for manufacturing an interposer according to example embodiments, such as the interposer 100 of FIG. 1.

FIG. 6 is a cross-sectional view illustrating an operation of forming the first redistribution structure 120 on a carrier 300

Referring to FIG. 6, the first redistribution structure 120 is formed on the carrier 300. First, the carrier 300 is provided. In an example embodiment, the carrier 300 may include a silicon-based material such as glass or silicon oxide, an organic material, other materials such as aluminum oxide, any combination thereof, etc.

Next, a first dielectric 121 is formed on the carrier 300. In an example embodiment, the first dielectric 121 may include a photoimageable dielectric (PID) (a photosensitive dielectric) to be used in a redistribution process. In an example embodiment, the photoimageable dielectric (PID) may include a polyimide-based photosensitive polymer, a novolac-based photosensitive polymer, polybenzoxazole, a silicon-based polymer, an acrylate-based polymer, or an epoxy-based polymer. In an example embodiment, the first dielectric 121 may be formed by spin coating.

After the first dielectric 121 is formed, the first dielectric 121 is selectively etched to form via holes, and the via holes are filled with a conductive material to form the first redistribution vias 122.

Subsequently, an additional first dielectric 121 is deposited on the first redistribution vias 122 and the first dielectric 121, and the disposed additional first dielectric 121 is selectively etched to form openings, and the openings are filled with a conductive material to form the first redistribution lines 123.

Next, an additional first dielectric 121 is deposited on the first redistribution lines 123 and the first dielectric 121, and the disposed additional first dielectric 121 is selectively etched to form via holes, and the via holes are filled with a conductive material to form the second redistribution vias 124.

Subsequently, an additional first dielectric 121 is deposited on the second redistribution vias 124 and the first dielectric 121, and the disposed additional first dielectric 121 is selectively etched to form openings, and the openings are filled with a conductive material to form the second redistribution lines 125.

Next, an additional first dielectric 121 is deposited on the second redistribution lines 125 and the first dielectric 121, and the disposed additional first dielectric 121 is selectively etched to form via holes, and the via holes are filled with a conductive material to form the third redistribution vias 126.

In an example embodiment, each of the first redistribution vias 122, the first redistribution lines 123, the second redistribution vias 124, the second redistribution lines 125, and the third redistribution vias 126 may include any one or any combination of copper, aluminum, tungsten, nickel, gold, tin, titanium, and alloys thereof. In an example embodiment, each of the first redistribution vias 122, the first redistribution lines 123, the second redistribution vias 124, the second redistribution lines 125, and the third redistribution vias 126 may be formed by performing a sputtering process. In another example embodiment, each of the first redistribution vias 122, the first redistribution lines 123, the second redistribution vias 124, the second redistribution lines 125, and the third redistribution vias 126 may be formed by forming a seed metal layer and then performing an electroplating process.

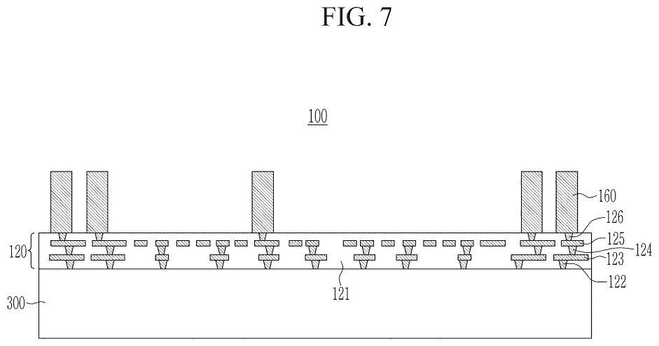

FIG. 7 is a cross-sectional view illustrating an operation of forming the second connection members 160 on the first redistribution structure 120.

Referring to FIG. 7, the second connection members 160 may be formed in the vertical direction on the first redistribution structure 120. In an example embodiment, the second connection members 160 may be formed by performing a sputtering process. In another example embodiment, the second connection members 160 may be formed by forming seed metal layers and then performing an electroplating process. In an example embodiment, the second connection members 160 may include any one or any combination of copper, aluminum, tungsten, nickel, gold, silver, chromium, antimony, tin, titanium, and alloys thereof.

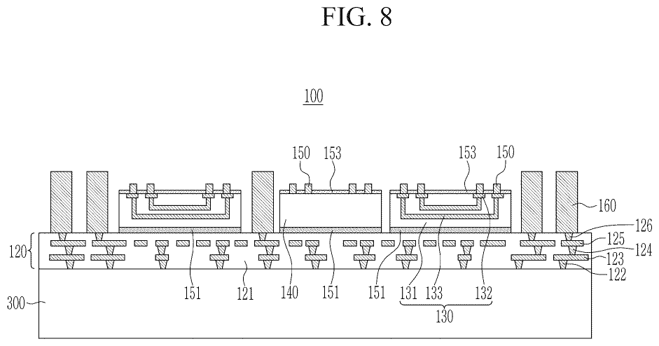

FIG. 8 is a cross-sectional view illustrating an operation of mounting the first device die 130 and the second device die 140 on the first redistribution structure 120.

Referring to FIG. 8, the first device die 130 and the second device die 140 are moved above the first redistribution structure 120 by applying a vacuum to the first connection members 150 formed on the upper surface of the first device die 130 and the upper surface of the second device die 140, and the first device die 130 and the second device die 140 are mounted on the first redistribution structure 120 by performing flip chip bonding.

According to example embodiments, in the process of moving the first device die 130 and the second device die 140 above the first redistribution structure 120 by applying a vacuum to the first connection members 150 formed on the upper surface of the first device die 130 and the upper surface of the second device die 140, it is possible to prevent the first connection members 150 from being short-circuited, prevent the first connection members 150 from coming off, and prevent defects from occurring in the first connection members 150.

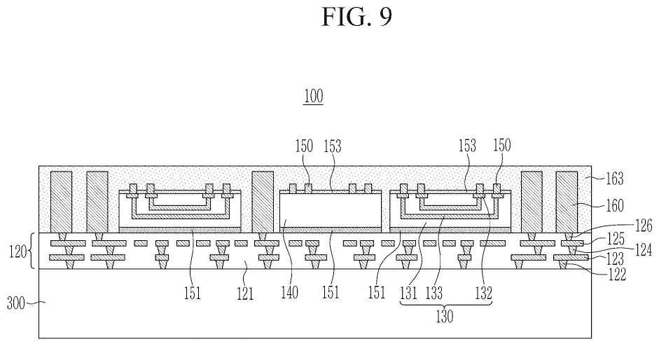

FIG. 9 is a cross-sectional view illustrating an operation of encapsulating the first device die 130, the second device die 140, the first connection members 150, the insulating members 153, and the second connection members 160 on the first redistribution structure 120.

Referring to FIG. 9, the first device die 130, the second device die 140, the first connection members 150, the insulating members 153, and the second connection members 160 are covered on the first redistribution structure 120 by the first molding material 163. In an example embodiment, the process of performing encapsulating by the first molding material 163 may include a compression molding or transfer molding process. In an example embodiment, the first molding material 163 may include an epoxy molding compound (EMC).

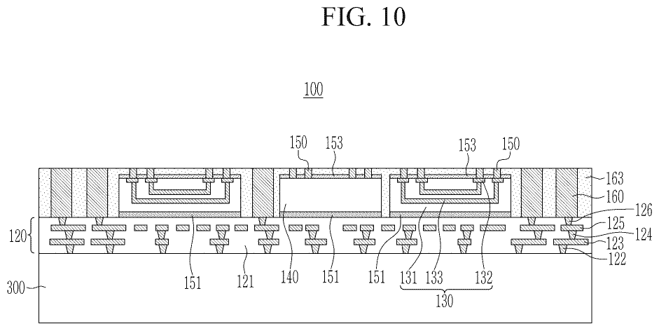

FIG. 10 is a cross-sectional view illustrating an operation of performing a chemical mechanical polishing (CMP) process on the first connection members 150, the second connection members 160, and the first molding material 163.

Referring to FIG. 10, by performing the chemical mechanical polishing (CMP) process to level the upper surfaces of the first connection members 150, the upper surfaces of the second connection members 160, and the upper surface of the first molding material 163, the upper surfaces of the first connection members 150, the upper surfaces of the second connection members 160, and the upper surface of the first molding material 163 are planarized. After the chemical mechanical polishing (CMP) process is performed, the upper surfaces of the first connection members 150 and the upper surfaces of the second connection members 160 are exposed. In an example embodiment, the upper surfaces of the first connection members 150, the upper surfaces of the second connection members 160, and the upper surface of the first molding material 163 may be planarized by performing a grinding process.

In the case where the height of the insulating members 153 is about 50% or more of the total height of the side surface of each of the first connection members 150, the insulating members 153 may hinder the upper surfaces of the first connection members 150 to be ground. For this reason, the height of the insulating members 153 may be about 50% or less of the total height of the side surface of each of the first connection members 150.

After the planarizing process, the side surfaces of the first connection members 150 may be covered by the combination of the insulating members 153 and the first molding material 163. According to example embodiments, it is possible to suppress warpage of the semiconductor package by variously changing the kinds of the insulating members 153 and the first molding material 163 and the ratio between the insulating members 153 and the first molding material 163.

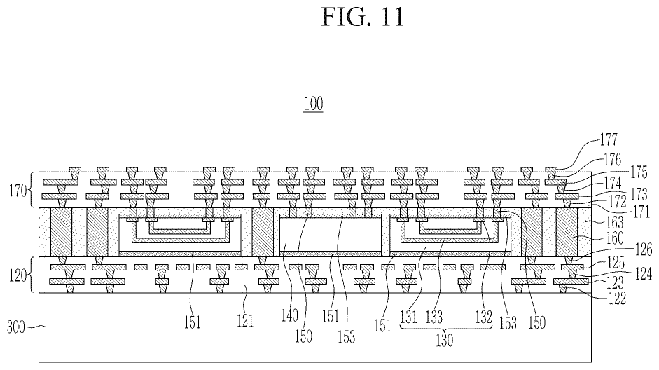

FIG. 11 is a cross-sectional view illustrating an operation of forming the second redistribution structure 170 on the first molding material 163.

Referring to FIG. 11, the second redistribution structure 170 is formed on the first connection members 150, the second connection members 160, and the first molding material 163.

First, a second dielectric 171 is formed on the first connection members 150, the second connection members 160, and the first molding material 163. In an example embodiment, the second dielectric 171 may include a photoimageable dielectric (PID) (a photosensitive dielectric) to be used in a redistribution process. In an example embodiment, the photoimageable dielectric (PID) may include a polyimide-based photosensitive polymer, a novolac-based photosensitive polymer, polybenzoxazole, a silicon-based polymer, an acrylate-based polymer, or an epoxy-based polymer. In an example embodiment, the second dielectric 171 may be formed by spin coating.

After the second dielectric 171 is formed, the second dielectric 171 is selectively etched to form via holes, and the via holes are filled with a conductive material to form the fourth redistribution vias 172.

Subsequently, an additional second dielectric 171 is deposited on the fourth redistribution vias 172 and the second dielectric 171, and disposed additional second dielectric 171 is selectively etched to form openings, and the openings are filled with a conductive material to form the third redistribution lines 173.

Next, an additional second dielectric 171 is deposited on the third redistribution lines 173 and the second dielectric 171, and the disposed additional second dielectric 171 is selectively etched to form via holes, and the via holes are filled with a conductive material to form the fifth redistribution vias 174.

Subsequently, an additional second dielectric 171 is deposited on the fifth redistribution vias 174 and the second dielectric 171, and the disposed additional second dielectric 171 is selectively etched to form openings, and the openings are filled with a conductive material to form the fourth redistribution lines 175.

Next, an additional second dielectric 171 is deposited on the fourth redistribution lines 175 and the second dielectric 171, and the disposed additional second dielectric 171 is selectively etched to form via holes, and the via holes are filled with a conductive material to form the sixth redistribution vias 176.

Subsequently, the second bonding pads 177 are formed by additionally depositing photoresist on the sixth redistribution vias 176 and the second dielectric 171, selectively exposing and developing the photoresist to form photoresist patterns including opening, and filling the openings with a conductive material.

In an example embodiment, each of the fourth redistribution vias 172, the third redistribution lines 173, the fifth redistribution vias 174, the fourth redistribution lines 175, the sixth redistribution vias 176, and the second bonding pads 177 may include any one or any combination of copper, aluminum, tungsten, nickel, gold, tin, titanium, and alloys thereof. In an example embodiment, each of the fourth redistribution vias 172, the third redistribution lines 173, the fifth redistribution vias 174, the fourth redistribution lines 175, the sixth redistribution vias 176, and the second bonding pads 177 may be formed by performing a sputtering process. In another example embodiment, each of the fourth redistribution vias 172, the third redistribution lines 173, the fifth redistribution vias 174, the fourth redistribution lines 175, the sixth redistribution vias 176, and the second bonding pads 177 may be formed by forming a seed metal layer and then performing an electroplating process.

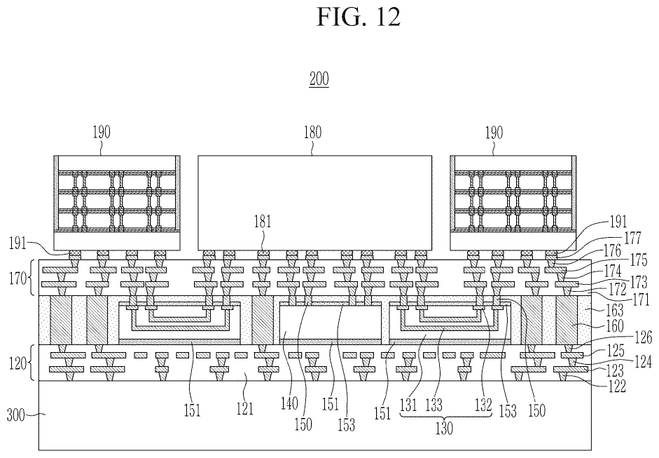

FIGS. 12 to 17 are cross-sectional views for explaining a method for manufacturing a semiconductor package, such as the semiconductor package of FIG. 3, according to example embodiments.

FIG. 12 is a cross-sectional view illustrating an operation of mounting the first semiconductor die 180 and one or more second semiconductor dies 190 on the second redistribution structure 170.

Referring to FIG. 12, the first semiconductor die 180 and one or more second semiconductor dies 190 are mounted on the second redistribution structure 170 by performing flip chip bonding. The first semiconductor die 180 is bonded to the second bonding pads 177 of the second redistribution structure 170 by the connection members 181 such that the first semiconductor die 180 and the second redistribution structure 170 are electrically coupled. One or more second semiconductor dies 190 are bonded to the second bonding pads 177 of the second redistribution structure 170 by the connection members 191 such that the second semiconductor dies 190 and the second redistribution structure 170 are electrically coupled.

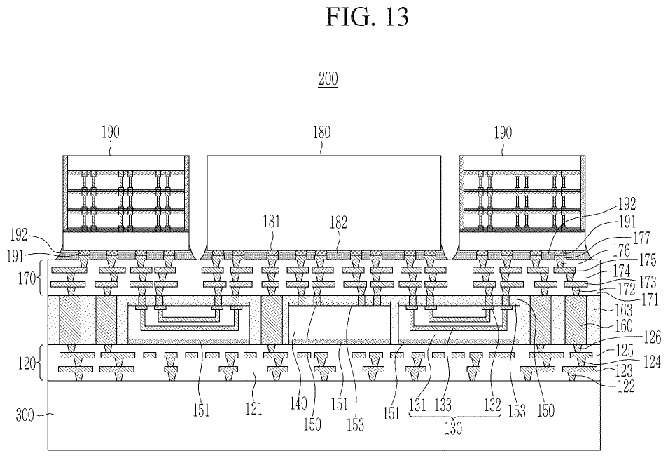

FIG. 13 is a cross-sectional view illustrating an operation of forming the insulating member 182 between the second redistribution structure 170 and the first semiconductor die 180 and forming one or more insulating members 192 between the second redistribution structure 170 and one or more second semiconductor dies 190.

Referring to FIG. 13, the insulating member 182 is formed between the second redistribution structure 170 and the first semiconductor die 180, and one or more insulating members 192 are formed between the second redistribution structure 170 and one or more second semiconductor dies 190. Therefore, it is possible to relieve stress between the second redistribution structure 170 and the first semiconductor die 180 and between the second redistribution structure 170 and one or more second semiconductor dies 190. The insulating member 182 surrounds the second bonding pads 177 and the connection members 181. One or more insulating members 192 surround the second bonding pads 177 and the connection members 191.

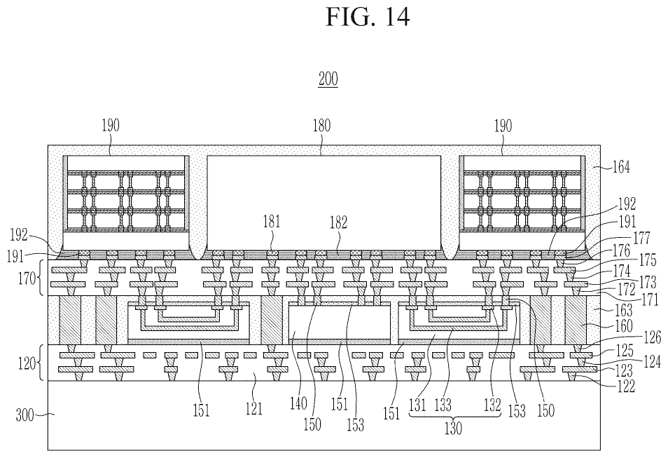

FIG. 14 is a cross-sectional view illustrating an operation of encapsulating the first semiconductor die 180 and one or more second semiconductor dies 190 on the second redistribution structure 170.

Referring to FIG. 14, the first semiconductor die 180 and one or more second semiconductor dies 190 are covered on the second redistribution structure 170 by the second molding material 164. In an example embodiment, the process of performing encapsulating by the second molding material 164 may include a compression molding or transfer molding process. In an example embodiment, the second molding material 164 may include an epoxy molding compound (EMC).

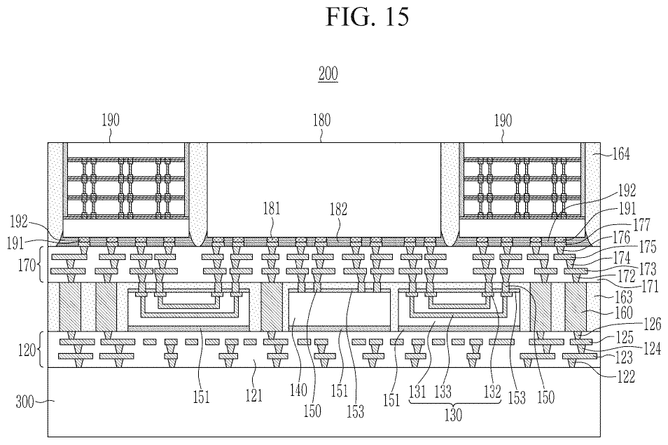

FIG. 15 is a cross-sectional view illustrating an operation of performing a chemical mechanical polishing (CMP) process on the second molding material 164.

Referring to FIG. 15, by performing the chemical mechanical polishing (CMP) process to level the upper surface of the second molding material 164, the upper surface of the second molding material 164 is planarized. After the chemical mechanical polishing (CMP) process is performed, the upper surface of the first semiconductor die 180 and the upper surfaces of one or more second semiconductor dies 190 are exposed.

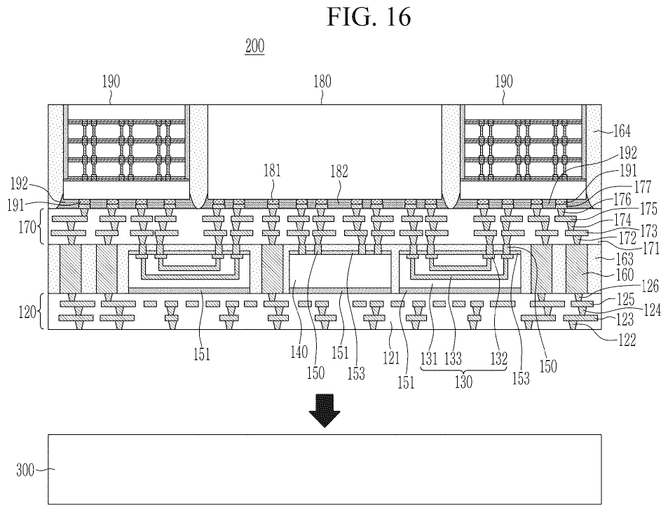

FIG. 16 is a cross-sectional view illustrating an operation of removing the carrier 300 from the first redistribution structure 120.

Referring to FIG. 16, the carrier 300 is removed from the lower surface of the first redistribution structure 120.

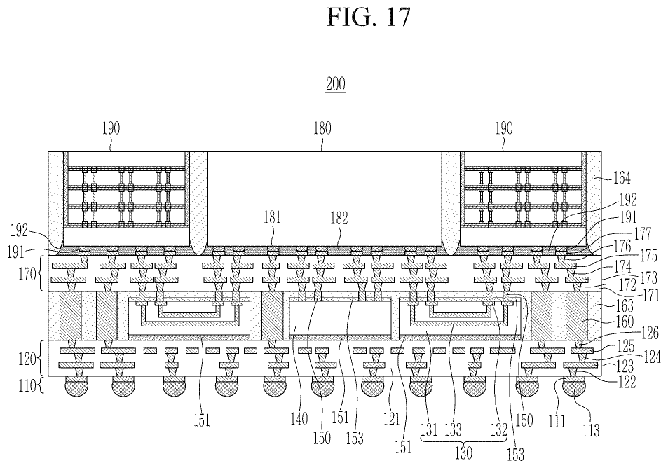

FIG. 17 is a cross-sectional view illustrating an operation of forming the external connection structure 110 on the lower surface of the first redistribution structure 120.

Referring to FIG. 17, the external connection structure 110 is formed on the lower surface of the first redistribution structure 120. The conductive pads 111 are formed below the first redistribution vias 122 of the first redistribution structure 120, and the external connection members 113 are formed below the conductive pads 111. In an example embodiment, the conductive pads 111 may be formed by a sputtering process, or by forming seed metal layers and then performing an electroplating process.

Thereafter, as shown in FIG. 3, the interposer 100 with the first semiconductor die 180 and one or more second semiconductor dies 190 is mounted on the printed circuit board 210 by performing flip chip bonding.

While aspects of example embodiments have been particularly shown and described, it will be understood that various changes in form and details may be made therein without departing from the spirit and scope of the following claims.

What is claimed is:

1. An interposer comprising:
a first redistribution structure;
a device die on the first redistribution structure, the device die having a first surface facing the first redistribution structure and a second surface which is opposite to the first surface;
a plurality of first connection members on the second surface of the device die;
an insulating member disposed on the second surface of the device die and covering first portions of side surfaces of the plurality of first connection members;
a plurality of second connection members on the first redistribution structure;
a molding material disposed on the first redistribution structure and covering each of the device die, second portions of the side surfaces of the plurality of first connection members, the insulating member, and the plurality of second connection members; and
a second redistribution structure on the molding material.

2. The interposer of claim 1, wherein the insulating member has a vertical thickness of about 5 μm to about 25 μm.

3. The interposer of claim 1, wherein a height of the insulating member is about 10% to about 50% of a height of the side surfaces of the plurality of first connection members.

4. The interposer of claim 1, wherein the insulating member comprises a photosensitive dielectric (PID).

5. The interposer of claim 1, wherein the insulating member is in direct contact with the second surface of the device die.

6. The interposer of claim 5, wherein an upper surface of the insulating member has a constant level in a horizontal direction.

7. The interposer of claim 1, wherein a lower surface of the insulating member is coplanar with lower surfaces of the plurality of first connection members.

8. The interposer of claim 1, wherein the plurality of first connection members comprises micro bumps.

9. The interposer of claim 1, wherein the molding material comprises an epoxy molding compound (EMC).

10. The interposer of claim 1, wherein the plurality of second connection members comprises conductive posts.

11. A semiconductor package comprising:
a substrate;
a first redistribution structure on the substrate;
a device die on the first redistribution structure, the device die having a first surface facing the first redistribution structure and a second surface which is opposite to the first surface;
a plurality of first connection members on the second surface of the device die;
an insulating member disposed on the second surface of the device die and covering first portions of side surfaces of the plurality of first connection members;
a plurality of second connection members on the first redistribution structure;
a molding material disposed on the first redistribution structure and covering each of the device die, second portions of the side surfaces of the plurality of first connection members, the insulating member, and the plurality of second connection members;
a second redistribution structure on the molding material;
a first semiconductor die on the second redistribution structure; and
a second semiconductor die on the second redistribution structure adjacent the first semiconductor die.

12. The semiconductor package of claim 11, wherein the device die comprises a bridge die.

13. The semiconductor package of claim 12, wherein the bridge die comprises a silicon bridge die.

14. The semiconductor package of claim 12, wherein the bridge die connects the first semiconductor die to the second semiconductor die.

15. The semiconductor package of claim 11, wherein the device die comprises a surface mount device (SMD).

16. The semiconductor package of claim 15, wherein the SMD comprises an integrated stack capacitor (ISC) structure.

17. A method of manufacturing an interposer, the method comprising:
providing a device die having a first surface and a second surface which is opposite to the first surface;
forming a plurality of first connection members on the second surface of the device die;
forming an insulating member on the second surface of the device die, wherein the insulating member covers first portions of side surfaces of the plurality of first connection members;
forming a first redistribution structure on a carrier;
forming a plurality of second connection members on the first redistribution structure;
attaching the first surface of the device die to the first redistribution structure;
covering each of the device die, the plurality of first connection members, the insulating member, and the plurality of second connection members on the first redistribution structure with a molding material;
planarizing the molding material, the plurality of first connection members, and the plurality of second connection members, wherein the molding material covers each of the device die, second portions of the side surfaces of the plurality of first connection members, the insulating member, and the plurality of second connection members; and
forming a second redistribution structure on the molding material.

18. The method of manufacturing the interposer according to claim 17, wherein the forming the insulating member on the second surface of the device die comprises spin coating the insulating member on the second surface of the device die.

19. The method of manufacturing the interposer according to claim 17, wherein the attaching the first surface of the device die to the first redistribution structure comprises attaching the first surface of the device die to the first redistribution structure by die attach film (DAF).

20. The method of manufacturing the interposer according to claim 17, wherein the planarizing comprises grinding the molding material, the plurality of first connection members, and the plurality of second connection members.
